(19) United States
(12) Patent Application Publication
(10) Pub. No.: US 2024/0414950 A1
(43) Pub. Date: Dec. 12, 2024

(54) DISPLAY DEVICE AND METHOD OF MANUFACTURING DISPLAY DEVICE

(71) Applicant: Samsung Display Co., Ltd., Yongin-si (KR)

(72) Inventor: Chun Gi YOU, Yongin-si (KR)

(21) Appl. No.: 18/620,497

(22) Filed: Mar. 28, 2024

(30) Foreign Application Priority Data
Jun. 7, 2023 (KR) 10-2023-0073055

(51) Int. Cl. H10K 59/122; H10K 59/12

(52) U.S. Cl. CPC H10K 59/122; H10K 59/1201

(57) ABSTRACT

A display device includes: pixels arranged in a display area; a pixel circuit layer including a pixel circuit; and a partition wall on the pixel circuit layer in the display area and in a non-display area. The non-display area is an area other than the display area. The partition wall includes a pixel defining layer and a separator on the pixel defining layer, and, in the non-display area, one end portion of the pixel defining layer and one end portion of the separator do not overlap with each other in a plan view.

### CROSS-REFERENCE TO RELATED APPLICATION

The present application claims priority to and the benefit of Korean Patent Application No. 10-2023-0073055, filed on Jun. 7, 2023, in the Korean Intellectual Property Office, the entire disclosure of which is incorporated herein by reference.

### BACKGROUND

### 1. Field

Aspects of embodiments of the present disclosure relate to a display device and a method of manufacturing the display device.

### 2. Description of the Related Art

With the development of information technologies, the importance of a display device, which is a connection medium between a user and information, is increasing.

The display device may have a display area in which pixels are disposed to display an image and a non-display area, which is an area other than the display area. Also, the display device may include electrodes (e.g., a cathode electrode) for supplying a power source to the pixels, and the electrodes of the display device may be deposited in the display area and in a portion of the non-display area.

An edge of an area in which an electrode of the display device is deposited may be defined as (or may a part of) the non-display area. For example, the electrode may be disposed throughout the display area and the non-display area.

An electrode of the display device is patterned on another layer to be in contact with the other layer to which the electrode is directly adjacent. When the electrode is insufficiently adhered to the other layer to which the electrode is directly adjacent, the electrode may lift in the non-display area. This may deteriorate the performance of the display device, and accordingly, research for maintaining a sufficient adhesion state by appropriately disposing an electrode on another layer in the non-display area of the display device has been continuously conducted.

### SUMMARY

Embodiments of the present disclosure include a display device and a method of manufacturing the display device in which a lifting risk of an electrode in a non-display area of the display device is reduced.

In accordance with an embodiment of the present disclosure, a display device includes: a display area in which pixels are arranged; a pixel circuit layer including a pixel circuit; and a partition wall on the pixel circuit layer in the display area and a non-display area. The non-display area is an area other than the display area. The partition wall includes a pixel defining layer and a separator on the pixel defining layer, and, in the non-display area, one end portion of the pixel defining layer and one end portion of the separator do not overlap with each other in a plan view.

The pixel defining layer may include: a first pixel defining layer on the pixel circuit layer, the first pixel defining layer having a first defining layer width; and a second pixel defining layer on the first pixel defining layer, the second pixel defining layer having a second defining layer width. The separator may include: a first separator on the pixel defining layer, the first separator having a first separator width; and a second separator on the first separator, the second separator having a second separator width.

The first defining layer width may be larger than the second defining layer width. The pixel defining layer may have a non-flat side surface.

The first separator width may be smaller than the second defining layer width. The second separator width may be smaller than the first separator width.

The separator may have a curved surface. The second separator may be inward of the first separator in a direction in which a plane on which the pixel circuit layer is arranged extends.

The pixel defining layer may further include a third pixel defining layer on the second pixel defining layer, the third pixel defining layer having a third defining layer width. The separator may further include a third separator on the second separator, the third separator having a third separator width.

End portions of the first pixel defining layer, the second pixel defining layer, and the third pixel defining layer may not overlap with each other in the plan view.

End portions of the first pixel defining layer, the second pixel defining layer, and the third pixel defining layer may overlap with each other in the plan view.

End portions of the first separator and the third pixel defining layer may not overlap with each other in the plan view. The second separator width may be smaller than each of the first separator width and the third separator width.

End portions of the first separator and the third pixel defining layer may not overlap with each other in the plan view. The first separator width, the second separator width, and the third separator width may be the same.

End portions of the first separator and the third pixel defining layer may not overlap with each other in the plan view. The second separator width may be smaller than each of the first separator width and the third separator width.

The display device may further include a first electrode and a second electrode on the pixel circuit layer. The second electrode may include a (2-1)th electrode in the display area and a (2-2)th electrode in the non-display area. The (2-2)th electrode may be on the partition wall.

The (2-2)th electrode may cover side surfaces of the pixel defining layer and the separator.

In accordance with another embodiment of the present disclosure, a method of manufacturing a display device having a display area in which pixels are arranged and a non-display area other than the display area includes: depositing a base pixel defining layer on a pixel circuit layer in the display area and the non-display area and depositing a base separator on the base pixel defining layer; and etching the base separator. The etching of the base separator includes etching the base separator such that the base separator in the non-display area exposes at least a portion of the base pixel defining layer.

The depositing of the base pixel defining layer may include depositing a first base pixel defining layer on the pixel circuit layer and depositing a second base pixel defining layer on the first base pixel defining layer. The depositing of the base separator may include depositing a first base separator on the base pixel defining layer and depositing a second base separator on the first base separator.

The etching of the base separator may include etching the base separator such that the first base separator and the second base separator have the same width.

The etching of the base separator may further include etching the second base separator deeper than the first base separator such that the first base separator has a first separator width and the second base separator has a second separator width. The second separator width may be smaller than the first separator width.

The method may further include etching the base pixel defining layer. The etching of the base pixel defining layer may include etching the first base pixel defining layer to form a first pixel defining layer having a first defining layer width and etching the second base pixel defining layer to form a second pixel defining layer having a second defining layer width that is smaller than the first defining layer width by.

In accordance with another embodiment of the present disclosure, a method of manufacturing a display device including a display area in which pixels are arranged and a non-display area other than the display area includes: depositing a base pixel defining layer on a pixel circuit layer in the display area and the non-display area and depositing a base separator on the base pixel defining layer; etching the base separator; and etching the base pixel defining layer. The depositing of the base pixel defining layer includes depositing a first base pixel defining layer on the pixel circuit layer and depositing a second base pixel defining layer on the first base pixel defining layer. The depositing of the base separator includes depositing a first base separator on the base pixel defining layer and depositing a second base separator on the first base separator. The etching of the base pixel defining layer includes etching the first base pixel defining layer to form a first pixel defining layer having a first defining layer width, and etching the second base pixel defining layer to form a second pixel defining layer having a second defining layer width that is smaller than the first defining layer width. An end portion of the first pixel defining layer and an end portion of the second pixel defining layer do not overlap with each other in a plan view.

In the etching of the base separator, the first base separator may be etched to form a first separator having a first separator width, and the second base separator may be etched to form a second separator having a second separator width that is smaller than the first separator width. Each of the base separator and the base pixel defining layer may include an inorganic material. The inorganic material may include at least one selected from the group consisting of silicon nitride and silicon oxide.

### BRIEF DESCRIPTION OF THE DRAWINGS

FIG. 1 is a schematic plan view of a display device in accordance with an embodiment of the present disclosure.

FIG. 2 is a schematic cross-sectional view taken along the line A-A′ in FIG. 1.

FIG. 3 is a schematic cross-sectional view of a light emitting element in accordance with an embodiment of the present disclosure.

FIG. 4 is a block diagram describing an electrical connection structure of a light emitting element in accordance with an embodiment of the present disclosure.

FIG. 5 is an enlarged schematic view of the area EA1 in FIG. 1.

FIG. 6 is a view schematically illustrating a partition wall structure in accordance with an embodiment of the present disclosure.

FIG. 7 is a view schematically illustrating a partition wall structure in accordance with another embodiment of the present disclosure.

FIG. 8 is a view schematically illustrating a partition wall structure in accordance with another embodiment of the present disclosure.

FIG. 9 is a flowchart describing a method of manufacturing a display device in accordance with an embodiment of the present disclosure.

FIGS. 10 to 13 are schematic cross-sectional views illustrating steps of the method of manufacturing the display device described in FIG. 9.

FIG. 14 is a flowchart describing a method of manufacturing a display device in accordance with another embodiment of the present disclosure.

FIG. 15 is a schematic cross-sectional view illustrating a step of a method of manufacturing a display device in accordance with an embodiment of the present disclosure.

### DETAILED DESCRIPTION

The present disclosure may include various changes and different shapes, therefore the embodiments illustrated herein are only examples. These examples do not limit to present disclosure to certain shapes but apply to all the change and equivalent material and replacement. In the figures, dimensions of the various elements, layers, etc. may be exaggerated for clarity of illustration. The same reference numerals designate the same elements.

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the present disclosure. As used herein, the singular forms are intended to include the plural forms as well, unless the context clearly indicates otherwise.

It will be further understood that the terms “includes” and/or “including,” when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate, or plate is placed “on” or “above” another element indicates not only a case where the element is placed “directly on” or “just above” the other element but also a case where a further element is interposed between the element and the other element. On the contrary, an expression that an element such as a layer, region, substrate, or plate is placed “beneath” or “below” another element indicates not only a case where the element is placed “directly beneath” or “just below” the other element but also a case where a further element is interposed between the element and the other element.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Embodiments of the present disclosure generally relate to a display device and a method of manufacturing the display device. Hereinafter, a display device and a method of manufacturing the display device in accordance with embodiments of the present disclosure will be described with reference to the accompanying drawings.

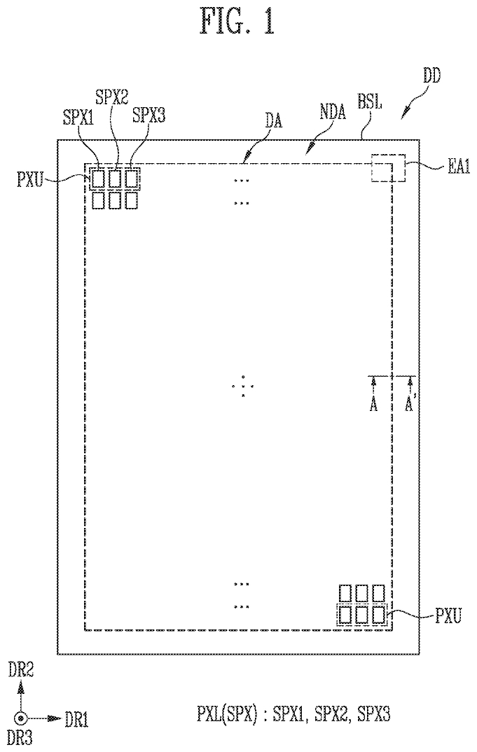

FIG. 1 is a schematic plan view of a display device in accordance with an embodiment of the present disclosure.

Referring to FIG. 1, the display device DD may be configured to emit light. The display device DD may include a light emitting element LD. In other embodiments, the display device DD may have various shapes. For example, the display device DD may have a rectangular plane shape having short sides in a first direction DR1 and long sides in a second direction DR2 crossing (or intersecting) the first direction DR1. In the present disclosure, the first direction DR1 may be a row direction of pixels PXL, and the second direction DR2 may be a column direction of pixels PXL. A third direction DR3 may be a display direction of the display device DD. In some embodiments, the display device DD may be applied to smartphones, notebook computers, tablet personal computers (PCs), wearable devices (e.g., a head mounted device, a smart watch, smart glasses, and the like), televisions, vehicle infotainment systems, or the like.

The display device DD may include a base layer BSL and pixels PXL disposed on the base layer BSL. The display device DD may further include a driving circuit (e.g., a scan driver and a data driver) for driving the pixels PXL, lines, and pads.

The display device DD may have a display area DA and a non-display area NDA. The non-display area NDA may be an area other than the display area DA. The non-display area NDA may surround (e.g., may extend around a periphery of) at least a portion of the display area DA.

The base layer BSL may form a base member of the display device DD. The base layer BSL may be a rigid or flexible substrate or film. For example, the base layer BSL may be a rigid substrate made of glass or tempered glass, a flexible substrate (or thin film) made of plastic or a metal material, or at least one insulating layer. The material and/or property of the base layer BSL is not particularly limited. In some embodiments, the base layer BSL may be substantially transparent. The term “substantially transparent” may mean that light can be transmitted therethrough with a reference (or predetermined) transmittance or more. In another embodiment, the base layer BSL may be translucent or opaque. In some embodiments, the base layer BSL may include a reflective material.

The display area DA may be an area in which the pixels PXL are disposed. The non-display area NDA may be an area in which the pixels PXL are not disposed. The driving circuit, the lines, and the pads, which are connected to the pixels PXL in the display area DA, may be disposed in the non-display area NDA.

In some embodiments, the pixels PXL (or sub-pixels SPX) may be arranged in various structures. For example, the pixels PXL (or sub-pixels SPX) may be arranged according to a stripe (e.g., S-tripe) arrangement structure, a PENTILE® (or diamond) arrangement structure, or the like. PENTILE® is a registered trademark of Samsung Display Co., Ltd. In some embodiments, sizes of the sub-pixels SPX may be different from each other (e.g., at least some of the sub-pixels SPX may have different sizes from each other), and the sub-pixels SPX may have various shapes. For example, in a plan view, the sub-pixels SPX may have a quadrangular shape and a hexagonal shape. However, the present disclosure is not limited thereto.

In some embodiments, the pixel PXL includes a light emitting element LD. The pixel PXL (or the sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may constitute one pixel unit PXU capable of emitting light of various colors.

For example, each of the first sub-pixel SPX1, the second sub-pixel SPX2, and the third sub-pixel SPX3 may emit light of one color. For example, the first sub-pixel SPX1 may be a red pixel for emitting light of red (e.g., a first color), the second sub-pixel SPX2 may be a green pixel for emitting light of green (e.g., a second color), and the third sub-pixel SPX3 may be a blue pixel for emitting light of blue (e.g., a third color). However, the color, kind, and/or number of first, second, and third sub-pixels SPX1, SPX2, and SPX3 constituting each pixel unit PXU is not limited to a specific example.

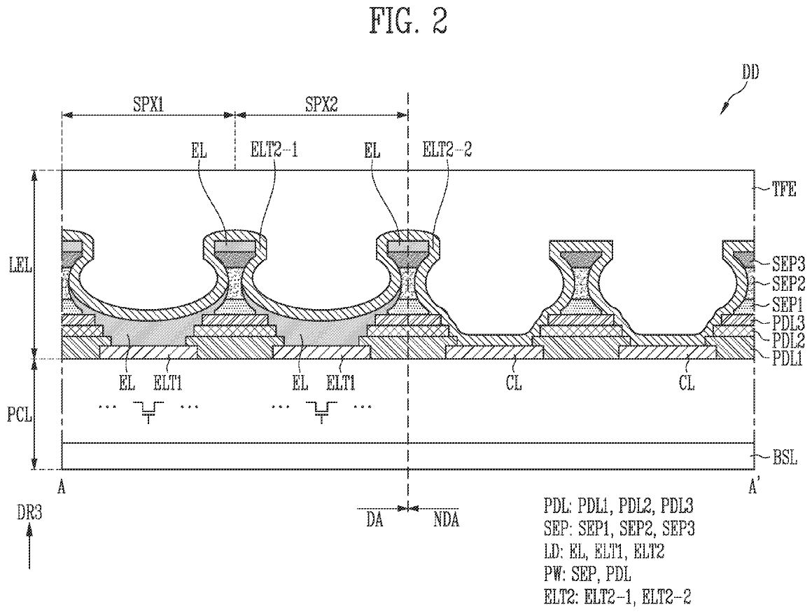

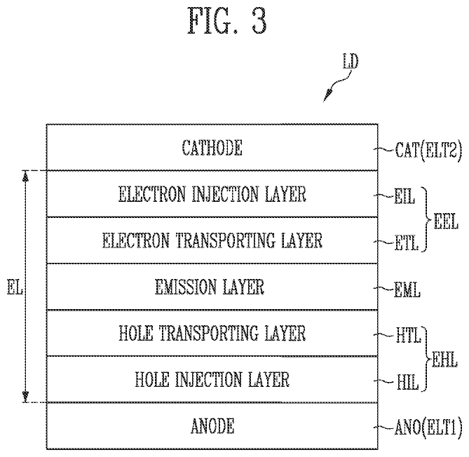

FIG. 2 is a schematic cross-sectional view taken along the line A-A′ in FIG. 1. FIG. 3 is a schematic cross-sectional view of a light emitting element in accordance with an embodiment of the present disclosure.

Referring to FIGS. 2 and 3, the display device DD includes a pixel circuit layer PCL and a light emitting element layer LEL.

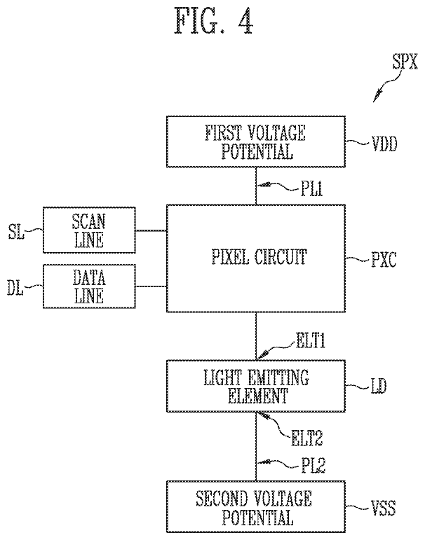

The pixel circuit layer PCL may include (or may be) a layer including a pixel circuit PXC (see, e.g., FIG. 4) for driving the light emitting elements LD. The pixel circuit layer PCL may include the base layer BSL, conductive layers for forming pixel circuits, and insulating layers disposed on the conductive layers.

In some embodiments, the pixel circuit PXC may include a thin film transistor and may be electrically connected to light emitting elements LD to provide an electrical signal for allowing (or for controlling) the light emitting elements LD to emit light.

The light emitting element layer LEL may be disposed on the pixel circuit layer PCL. In some embodiments, the light emitting element layer LEL may include a light emitting element LD, a partition wall PW, a connection electrode CL, and an encapsulation layer TFE.

The partition wall PW may define an area in which a light emitting part EL is disposed. For example, the light emitting part EL may be disposed between partition walls PW.

The partition wall PW may include a pixel defining layer PDL and a separator SEP disposed on the pixel defining layer PDL. The partition walls PW may be disposed in the display area DA and may be disposed in (may also be disposed in) the non-display area NDA. The partition walls PW may be spaced apart from each other.

The partition wall PW may be disposed on the pixel circuit layer PCL. The partition wall PW may have a protrusion structure protruding in one direction (e.g., a thickness direction of the base layer BSL or the third direction DR3) from the pixel circuit layer PCL.

The pixel defining layer PDL may define an area in which a first electrode ELT1 (e.g., an anode electrode) is disposed. In some embodiments, the pixel defining layer PDL may define the area in which the light emitting part EL is disposed.

In some embodiments, the pixel defining layer PDL may have a multi-layer structure. For example, the pixel defining layer PDL may include a first pixel defining layer PDL1, a second pixel defining layer PDL2 disposed on the first pixel defining layer PDL1, and a third pixel defining layer PDL3 disposed on the second pixel defining layer PDL2. However, the present disclosure is not limited thereto.

The separator SEP may physically separate light emitting parts EL of respective sub-pixels SPX that are adjacent to each other. For example, at least a portion of the light emitting parts EL may be separated from another adjacent light emitting part EL at an edge of a top surface of the separator SEP. For example, the separator SEP may physically separate a first sub-pixel SPX1 and a second sub-pixel SPX2 from each other in the display area DA.

In some embodiments, the separator SEP may have a multi-layer structure. For example, the separator SEP may include a first separator SEP1, a second separator SEP2 disposed on the first separator SEP1, and a third separator SEP3 disposed on the second separator SEP2. However, the present disclosure is not limited thereto.

The separator SEP and the pixel defining layer PDL may have a side surface having a step difference. For example, the side surface of the separator SEP and the pixel defining layer PDL may not be flat. Each of the separator SEP and the pixel defining layer PDL may include a portion protruding in a width direction thereof. For example, the separator SEP and the pixel defining layer PDL may have end portions which do not accord with (e.g., that are not aligned with) each other. The separator SEP and the pixel defining layer PDL may have end portions not overlapping with (e.g., offset from) each other in a plan view. One width of the separator SEP and one width of the pixel defining layer PDL may be different from each other. The width of each of the separator SEP and the pixel defining layer PDL may be defined with respect to a direction (e.g., the first direction DR1 or the second direction DR2) in which a plane having the base layer BSL disposed thereon extends.

The light emitting element LD may be disposed on the pixel circuit layer PCL. In some embodiments, the light emitting element LD may include a first electrode ELT1, a light emitting part EL, and the second electrode ELT2.

The first electrode ELT1 may be disposed on the pixel circuit layer PCL. The light emitting part EL may be disposed on the first electrode ELT1. The light emitting part EL may cover the first electrode ELT1. In some embodiments, the light emitting part EL may be disposed in an area defined by (e.g., an area between) the partition wall PW. For example, the light emitting part EL may be disposed in an area surrounded by (e.g., surrounded in a plan view by) the partition wall PW. The second electrode ELT2 may be disposed over (or on) the light emitting part EL. In some embodiments, the second electrode ELT2 may entirely cover the light emitting part EL.

In some embodiments, one surface of the light emitting part EL may be electrically connected to the first electrode ELT1, and the other surface (e.g., the opposite surface) of the light emitting part EL may be electrically connected to the second electrode ELT2. The first electrode ELT1 may be an anode electrode ANO with respect to the light emitting part EL, and the second electrode ELT2 may be a cathode electrode CAT with respect to the light emitting part EL.

In some embodiments, the first electrode ELT1 and the second electrode ELT2 may include a conductive material. For example, the conductive material may be (or may include) at least one selected from the group consisting of gold (Au), silver (Ag), aluminum (AI), molybdenum (Mo), chromium (Cr), titanium (Ti), nickel (Ni), neodymium (Nd), copper (Cu), and platinum (Pt). In some embodiments, the conductive material may be (or may include) at least one selected from the group consisting of silver nano wire (AgNW), Indium Tin Oxide (ITO), Indium Zinc Oxide (IZO), Indium Gallium Zinc Oxide (IGZO), Antimony Zinc Oxide (AZO), Indium Tin Zinc Oxide (ITZO), Zinc Oxide (ZnO), Tin Oxide (SnO₂), carbon nano tube, and graphene. However, the present disclosure is not limited thereto.

The light emitting part EL may have a multi-layer thin film structure including a light generation layer (e.g., an emission layer EML). The light emitting part EL may include a hole injection layer HIL for injecting holes, a hole transport layer HTL for increasing a hole recombination opportunity by suppressing movement of electrons, which are excellent in transportability of holes and are not combined in the emission layer EML, the emission layer EML for emitting light by recombination of the injected electrons and holes, an electron transport layer ETL for smoothly transporting the electrons to the light generation layer, and an electron injection layer EIL for injecting the electrons. The light emitting part EL may emit light based on an electrical signal provided from the anode electrode ANO (e.g., the first electrode ELT1) and the cathode electrode CAT (e.g., the second electrode ELT2).

In some embodiments, the second electrode ELT2 may be manufactured to be entirely deposited in the display area DA. Accordingly, a power source supplied to the second electrode ELT2 may be provided to (e.g., may be commonly provided to) each sub-pixel SPX. Also, the second electrode ELT2 may be manufactured to be deposited in at least a partial area of the non-display area NDA from the display area DA.

In some embodiments, the second electrode ELT2 may include a (2-1)th electrode ELT2-1 disposed (e.g., formed) in the display area DA and a (2-2)th electrode ELT2-2 disposed (e.g., formed) in the non-display area NDA. The (2-1)th electrode ELT2-1 and the (2-2)th electrode ELT2-2 may be formed through the same process. For example, the (2-1)th electrode ELT2-1 and the (2-2)th electrode ELT2-2 may be deposited through the same process. Accordingly, the (2-1)th electrode ELT2-1 and the (2-2)th electrode ELT2-2 may include the same material. The (2-1)th electrode ELT2-1 and the (2-2)th electrode ELT2-2 may be integrally formed.

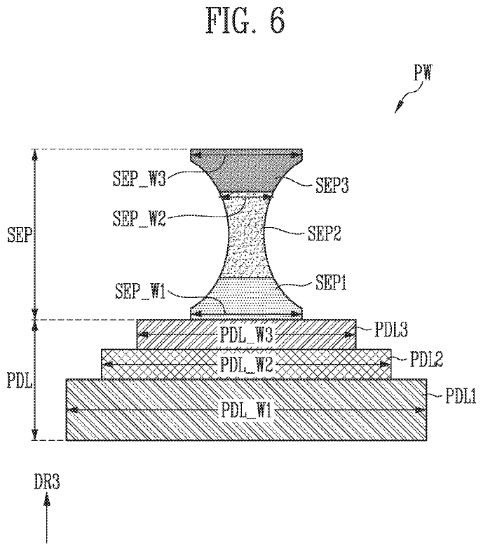

In the display device DD in accordance with an embodiment of the present disclosure, because the separator SEP and the pixel defining layer PDL have end portions that do not accord with (or align with) each other, a contact area with a lower layer on which a conductive material is deposited is increased when the (2-2)th electrode ELT2-2 is deposited in the non-display area NDA. Accordingly, the adhesion with a surface on which the (2-2)th electrode ELT2-2 is deposited is increased. This will be described in more detail below with reference to, for example, FIG. 6.

The (2-2)th electrode ELT2-2 may be electrically connected to the connection electrode CL disposed on the pixel circuit layer PCL. The connection electrode CL may be formed with (e.g., may be formed concurrently with) the first electrode ELT1 through the same process. For example, the connection electrode CL and the first electrode ELT1 may be deposited through the same process. Accordingly, the connection electrode CL and the first electrode ELT1 may include the same material.

The encapsulation layer TFE may be disposed over the light emitting element LD (e.g., the second electrode ELT2). The encapsulation layer TFE may cancel (e.g., may planarize) a step difference caused by the light emitting element LD and the pixel defining layer PDL. The encapsulation layer TFE may include a plurality of insulating layers covering the light emitting element LD. In some embodiments, the encapsulation layer TFE may have a structure in which an inorganic layer and an organic layer are alternately stacked on each other. In some embodiments, the encapsulation layer TFE may be a thin film encapsulation layer.

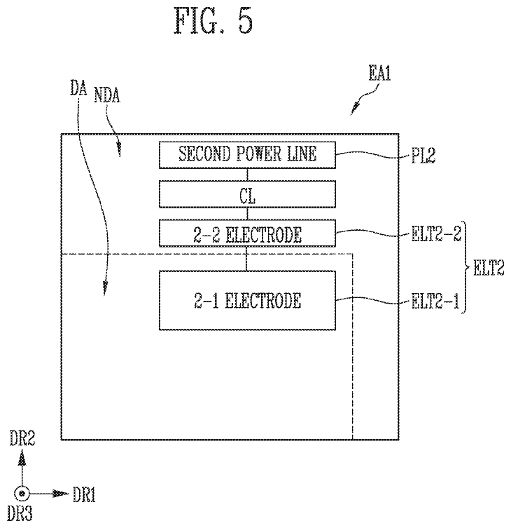

FIG. 4 is a block diagram describing an electrical connection structure of a light emitting element in accordance with an embodiment of the present disclosure. For example, FIG. 4 may illustrate an electrical connection structure including a pixel circuit PXC corresponding to each sub-pixel SPX. FIG. 5 is an enlarged schematic view of the area EA1 in FIG. 1. FIG. 5 is a schematic plan view illustrating a connection relationship between a second power line PL2 and a second electrode ELT2 in accordance with an embodiment of the present disclosure. For example, FIG. 5 may illustrate a structure in which a (2-1)th electrode ELT2-1 in the display area DA is electrically connected to the second power line PL2 formed in the non-display area NDA.

Referring to FIG. 4, the sub-pixel SPX may include a pixel circuit PXC configured to drive a light emitting element LD.

The pixel circuit PXC may include at least one circuit element. For example, the pixel circuit PXC may include transistors and a storage capacitor. For example, the pixel circuit PXC may include a driving transistor, a switching transistor, and a storage capacitor. However, the present disclosure is not limited thereto.

The pixel circuit PXC may be electrically connected to a scan line SL and a data line DL. The scan line SL may supply a scan signal to the pixel circuit PXC. In some embodiments, the scan line SL may be electrically connected to a gate electrode of the switching transistor of the pixel circuit PXC. The light emitting element LD may be configured to emit light corresponding to a data signal provided from the data line DL.

The pixel circuit PXC may be electrically connected to a first power line PL1 and a second power line PL2. For example, a first electrode ELT1 of the light emitting element LD may be electrically connected to the pixel circuit PXC and the first power line PL1, and a second electrode ELT2 of the light emitting element LD may be electrically connected to the second power line PL2. The first power line PL1 and the second power line PL2 may be disposed on the base layer BSL.

A power source of the first power line PL1 and a power source of the second power line PL2 may have different potentials. For example, the power source of the first power line PL1 may be a high-potential pixel power source supplied with a power source from a first voltage potential VDD, and the power source of the second power line PL2 may be a low-potential pixel power source supplied with a power source from a second voltage potential VSS. A potential difference between the power source of the first power line PL1 and the power source of the second power line PL2 may be equal to or higher than a threshold voltage of light emitting element LD.

The first power line PL1 may be electrically connected to the pixel circuit PXC (e.g., the driving transistor of the pixel circuit PXC). The second power line PL2 may be electrically connected to a cathode electrode (e.g., the second electrode ELT2) of the light emitting element LD.

In some embodiments, the second power line PL2 may be electrically connected to the second electrode ELT2. For example, in conjunction with FIG. 5, the second electrode ELT2 may be applied with a power source through the second power line PL2 disposed in the non-display area NDA. In some embodiments, a (2-1)th electrode ELT2-1 disposed in the display area DA may be adjacent to a (2-2)th electrode ELT2-2 disposed in the non-display area NDA. The (2-1)th electrode ELT2-1 disposed in the display area DA may be electrically connected to the (2-2)th electrode ELT2-2 disposed in the non-display area NDA. In some embodiments, the (2-2)th electrode ELT2-2 in the non-display area NDA may be adjacent to a connection electrode CL. The (2-2)th electrode ELT2-2 in the non-display area NDA may be electrically connected to the connection electrode CL. In some embodiments, the connection electrode CL may be adjacent to the second power line PL2. The connection electrode CL may be electrically connected to the second power line PL2. Accordingly, the second electrode ELT2 formed throughout the display area DA and the non-display area NDA may be electrically connected to the second power line PL2 in the non-display area NDA. As described above, because the (2-1)th electrode ELT2-1 in the display area DA and the second power line PL2 are electrically connected to each other, the power source provided by the second power line PL2 can be applied to the entire display area DA.

Light emitting elements LD may be connected in a forward direction between the first power line PL1 and the second power line PL2 to respectively form effective light sources. These effective light sources together constitute the light emitting elements LD of the sub-pixel SPX.

The light emitting elements LD may emit light with a luminance corresponding to a driving current supplied through the pixel circuit PXC. The pixel circuit PXC may supply a driving current corresponding to the data signal to the light emitting element LD during each frame period. The light emitting element LD may emit light having a luminance corresponding to a current flowing therethrough.

Hereinafter, structural features of the partition wall PW included in the display device DD will be described with reference to FIGS. 2 and 6. FIG. 6 is a view schematically illustrating a partition wall structure in accordance with an embodiment of the present disclosure.

Referring to FIGS. 2 and 6, the partition wall PW may have a multi-layer structure including a pixel defining layer PDL and a separator SEP disposed on the pixel defining layer PDL. The pixel defining layer PDL may include a first pixel defining layer PDL1, a second pixel defining layer PDL2, and a third pixel defining layer PDL3. The separator SEP may include a first separator SEP1, a second separator SEP2, and a third separator SEP3.

The first pixel defining layer PDL1 may be adjacent to the pixel circuit layer PCL. In some embodiments, the first pixel defining layer PDL1 may be disposed directly on the pixel circuit layer PCL. The first pixel defining layer PDL1 may physically separate the first electrodes ELT1 from each other. The first pixel defining layer PDL1 may physically separate the connection electrodes CL from each other. The first pixel defining layer PDL1 may cover end portions of the first electrodes ELT1 and the connection electrodes CL. The first pixel defining layer PDL1 may have step differences with the first electrodes ELT1 and the connection electrodes CL. Because the first pixel defining layer PDL1 has step differences with the first electrodes ELT1 and the connection electrodes CL, the deposition surface area of the (2-2)th electrode ELT2-2 can be increased as compared with when the first pixel defining layer PDL1 does not have any step differences with the first electrodes ELT1 and the connection electrodes CL (e.g., when a height of the first pixel defining layer PDL1 and a height of the connection electrodes CL are the same).

The first pixel defining layer PDL1 may have a first defining layer width PDL_W1. The first defining layer width PDL_W1 may be a largest width defined in the first pixel defining layer PDL1. The first defining layer width PDL_W1 may be a widest width from among widths of the partition wall PW. Hereinafter, widths of the pixel defining layer PDL defined in the present disclosure may be defined with respect to a direction (e.g., the first direction DR1 or the second direction DR2) in which a plane having the base layer BSL, or the pixel circuit layer PCL disposed thereon, extends.

The second pixel defining layer PDL2 may be disposed on the first pixel defining layer PDL1. The second pixel defining layer PDL2 may be adjacent to the first pixel defining layer PDL1. In some embodiments, the second pixel defining layer PDL2 may be disposed directly on the first pixel defining layer PDL1.

The second pixel defining layer PDL2 may have a second defining width PDL_W2. The second defining width PDL_W2 may be a largest width defined in the second pixel defining layer PDL2. The second defining width PDL_W2 may be smaller than the first defining width PDL_W1. Accordingly, the second pixel defining layer PDL2 and the first pixel defining layer PDL may have end portions that do not accord with (e.g., that are not aligned with) each other in a plan view. The end portion of the second pixel defining layer PDL2 and the end portion of the first pixel defining layer PDL1 may not overlap with each other in a plan view. The second pixel defining layer PDL2 may be formed inwardly of the first pixel defining layer PDL1 in the width direction. The first pixel defining layer PDL1 may have a structure protruding outwardly of the second pixel defining layer PDL2 in the width direction.

The third pixel defining layer PDL3 may be disposed on the second pixel defining layer PDL2. The third pixel defining layer PDL3 may be adjacent to the second pixel defining layer PDL2. In some embodiments, the third pixel defining layer PDL3 may be disposed directly on the second pixel defining layer PDL2.

The third pixel defining layer PDL3 may have a third defining layer width PDL_W3. The third defining layer width PDL_W3 may be a largest width defined in the third pixel defining layer PDL3. The third defining layer width PDL_W3 may be smaller than the second defining layer width PDL_W2. Accordingly, the third pixel defining layer PDL3 and the second pixel defining layer PDL2 may have end portions that do not accord with (e.g., that are not aligned with) each other in a plan view. The end portion of the third pixel defining layer PDL3 and the end portion of the second pixel defining layer PDL2 may not overlap with each other in a plan view. The third pixel defining layer PDL3 may be formed inwardly of the second pixel defining layer PDL2 in the width direction. The second pixel defining layer PDL2 may have a structure protruding outwardly of the third pixel defining layer PDL3 in the width direction.

The first pixel defining layer PDL1, the second pixel defining layer PDL2, and the third pixel defining layer PDL3 may have end portions that do not accord with one another. The end portions of the first pixel defining layer PDL1, the second pixel defining layer PDL2, and the third pixel defining layer PDL3 may not overlap with one another in a plan view.

However, the present disclosure is not limited thereto. For example, in a plan view, the first pixel defining layer PDL1 and the second pixel defining layer PDL2 may have end portions that accord with each other (e.g., that are aligned with each other) and have end portions that do not accord with (e.g., that are not aligned with) an end portion of the third pixel defining layer PDL3.

The first pixel defining layer PDL1, the second pixel defining layer PDL2, and the third pixel defining layer PDL3 may have end portions that do not accord with one another in a plan view, and the pixel defining layer PDL may have curves. For example, a side surface of the pixel defining layer PDL may not be flat, and a section of the pixel defining layer PDL may have a stepped shape with respect to a sectional direction defined in FIG. 2.

According to a conventional display structure, the first pixel defining layer PDL1, the second pixel defining layer PDL2, and the third pixel defining layer PDL3 had end portions that accord with one another (e.g., the end portions overlapped with one another on a plane), and a section of the pixel defining layer PDL had a roughly quadrangular shape with respect to the sectional direction defined in FIG. 2. Accordingly, when the (2-2)th electrode ELT2-2 was deposited on the non-display area NDA, sufficient surface area for allowing the (2-2)th electrode ELT2-2 to be adhered on the pixel defining layer PDL was not secured. For example, it might be difficult for the (2-2)th electrode ELT2-2 to cover at least a portion of the pixel defining layer PDL in the non-display area NDA, and a case where the (2-2)th electrode ELT2-2 was deposited on a structure corresponding to the third separator SEP3 frequently happened. Accordingly, a lifting phenomenon of the (2-2)th electrode ELT2-2 in the non-display area NDA might occur.

According to the partition wall PW structure in accordance with an embodiment of the present disclosure, curves can be formed at the pixel defining layer PDL (e.g., the side surface of the pixel defining layer PDL), and the surface area of the pixel defining layer PDL on which the (2-2)th electrode ELT2-2 can be deposited is increased. For example, due to the curves that are formed at the partition wall PW in the non-display area NDA, the (2-2)th electrode ELT2-2 may be deposited to have a relatively wide area as compared with when curves are not formed at the partition wall PW. For example, the (2-2)th electrode ELT2-2 may cover the side surface of the pixel defining layer PDL at where the curves are formed in the non-display area NDA. As the area at where the (2-2)th electrode ELT2-2 can be deposited increases, the adhesion between the (2-2)th electrode ELT2-2 and the pixel defining layer PDL can be increased, and accordingly, the lifting phenomenon of the (2-2)th electrode ELT2-2 in the non-display area NDA may not occur.

The pixel defining layer PDL may include an inorganic material. For example, the pixel defining layer PDL may include at least one of silicon oxide (SiOₓ) and silicon nitride (SiNₓ).

In some embodiments, the first pixel defining layer PDL1 and the third pixel defining layer PDL3 may include the same material, and the second pixel defining layer PDL2 may include a material different from the material of the first pixel defining layer PDL1 and the third pixel defining layer PDL3. For example, the first pixel defining layer PDL1 and the third pixel defining layer PDL3 may include silicon oxide (SiOₓ), and the second pixel defining layer PDL2 may include silicon nitride (SiNₓ). However, the present disclosure is not limited thereto.

In another embodiment, the pixel defining layer PDL may include an organic material. For example, the pixel defining layer PDL may include at least one selected from the group consisting of an acrylic resin, an epoxy resin, a phenolic resin, a polyamide resin, and a polyimide resin.

The first separator SEP1 may be disposed on the third pixel defining layer PDL3. The first separator SEP1 may adjacent to the third pixel defining layer PDL3. In some embodiments, the first separator SEP1 may be disposed directly on the third pixel defining layer PDL3.

In some embodiments, the first separator SEP1 may have two or more different widths. For example, the first separator SEP1 may have a first separator width SEP_W1 at one end portion thereof and may have a width smaller than the first separator width SEP_W1 at the other end portion thereof.

The first separator width SEP_W1 may be a largest width defined in the first separator SEP1. The first separator width SEP_W1 may be smaller than the third defining layer width PDL_W3. Accordingly, the first separator SEP1 and the third pixel defining layer PDL3 may have end portions that do not accord with each other. The end portion of the first separator SEP1 and the end portion of the third pixel defining layer PDL3 may not overlap with each other in a plan view. However, the present disclosure is not limited thereto. The first separator width SEP_W1 may be equal to the third defining layer width PDL_W3. The first separator SEP1 and the third pixel defining layer PDL3 may have end portions which accord with each other. The end portion of the first separator SEP1 and the end portion of the third pixel defining layer PDL3 may overlap with each other in a plan view.

The second separator SEP2 may be disposed on the first separator SEP1. The second separator SEP2 may be adjacent to the first separator SEP1. In some embodiments, the second separator SEP2 may be disposed directly on the first separator SEP1.

The second separator SEP2 may have two or more different widths. For example, the second separator SEP2 may have the same width at one end portion and the other end portion thereof and may have a width in a central area that is narrower than the width at the one end portion and the other end portion thereof. The second separator SEP2 may have a second separator width SEP_W2 at the one end portion and the other end portion thereof and may have a width in the central area that is smaller than the second separator width SEP_W2.

The second separator width SEP_W2 may be a largest width defined in the second separator SEP2. The second separator width SEP_W2 may be smaller than the first separator width SEP_W1. Because the second separator width SEP_W2 is smaller than the first separator width SEP_W1, the second separator SEP2 may have a structure that extends inwardly of the first separator SEP1.

The third separator SEP3 may be disposed on the second separator SEP2. The third separator SEP3 may be adjacent to the second separator SEP2. In some embodiments, the third separator SEP3 may be disposed directly on the second separator SEP2.

The third separator SEP3 may have two or more different widths. For example, the third separator SEP3 may have a third separator width SEP_W3 at one end portion thereof (e.g., at an end portion thereof opposite to the second separator SEP2) and may have a width narrower than the third separator width SEP_W3 at the other end portion thereof.

The third separator width SEP_W3 may be a largest width defined in the third separator SEP3. The third separator width SEP_W3 may be larger than the second separator width SEP_W2. In some embodiments, the third separator width SEP_W3 may be equal to the first separator width SEP_W1. However, the present disclosure is not limited thereto. Because each of the third separator width SEP_W3 and the first separator width SEP_W1 is larger than the second separator width SEP_W2, the separator SEP may have an under-cut structure in which the first separator SEP1 and the third separator SEP3 protrude outwardly of the second separator SEP2.

Because the separator SEP has the under-cut structure in which the first separator SEP1 and the third separator SEP3 protrude outwardly of the second separator SEP2, the separator SEP may have a width which becomes narrower approaching the middle from one end portion and then becomes wider approaching the other end portion from the middle. The separator SEP may include a curved surface. Accordingly, a surface area for allowing the (2-2)th electrode ELT2-2 to be adhered on the separator SEP when the (2-2)th electrode ELT2-2 is deposited on the non-display area NDA can be increased as compared with the separator SEP that does not have a curved surface. For example, the (2-2)th electrode ELT2-2 may cover a side surface of the separator SEP when the (2-2)th electrode ELT2-2 is deposited on the non-display area NDA. Accordingly, the lifting phenomenon of the (2-2)th electrode ELT2-2 in the non-display area NDA can be prevented.

The separator SEP may include an inorganic material. For example, the separator SEP may include at least one of silicon oxide (SiOₓ) and silicon nitride (SiNₓ).

In some embodiments, the first separator SEP1 and the third separator SEP3 may include the same material, and the second separator SEP2 may include a material different from the material of the first separator SEP1 and the third separator SEP3. For example, the first separator SEP1 and the third separator SEP3 may include silicon nitride (SiNₓ), and the second separator SEP2 may include silicon oxide (SiOₓ). However, the present disclosure is not limited thereto. In another embodiment, the separator SEP may include an organic material. For example, the separator SEP may include at least one selected from the group consisting of an acrylic resin, an epoxy resin, a phenolic resin, a polyamide resin, and a polyimide resin.

The partition wall PW including the separator SEP and the pixel defining layer PDL in accordance with an embodiment of the present disclosure may be formed in at least a partial area of the non-display area NDA. The partition walls PW may be disposed to be spaced apart from each other. The partition wall PW may be disposed on the pixel circuit layer PCL to form (or to include) at least two protrusion structures on the pixel circuit layer PCL. Because the protrusion structure is formed in the non-display area NDA, the surface area with which the (2-2)th electrode ELT2-2 can be deposited when the (2-2)th electrode ELT2-2 is deposited on the non-display area NDA can be increased, and the lifting phenomenon of the (2-2)th electrode ELT2-2 in the non-display area NDA can be prevented.

The partition wall PW including the separator SEP and the pixel defining layer PDL in accordance with an embodiment of the present disclosure may have two or more widths that are different from each other. For example, a width of the pixel defining layer PDL and a width of the separator SEP may be different from each other. For example, the first pixel defining layer PDL1, the second pixel defining layer PDL2, the third pixel defining layer PDL3, and the second separator SEP2 may have different widths. Because the separator SEP and the pixel defining layer PDL have different widths, one end portion of the separator SEP and one end portion of the pixel defining layer PDL may not accord with (e.g., may not be aligned with) each other. The one end portion of the separator SEP and the one end portion of the pixel defining layer PDL may not overlap with each other in a plan view. Accordingly, the partition wall PW has curves, and the surface area on which the (2-2)th electrode ELT2-2 can be deposited is increased.

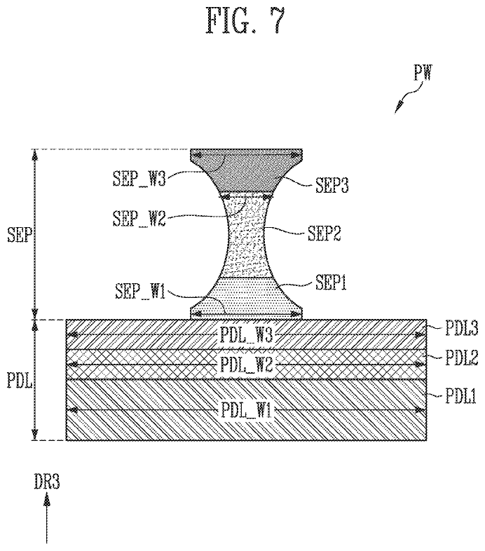

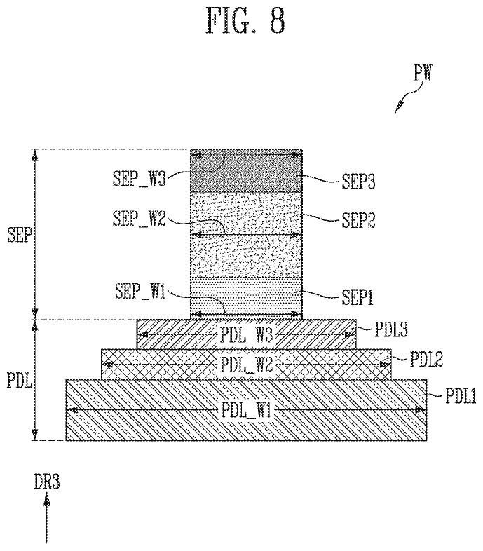

Hereinafter, partition wall PW structures in accordance with other embodiments of the present disclosure will be described with reference to FIGS. 7 and 8. In FIGS. 7 and 8, descriptions of portions that are the same or substantially the same as those described above will not be repeated. FIG. 7 is a view schematically illustrating a partition wall structure in accordance with another embodiment of the present disclosure. FIG. 8 is a view schematically illustrating a partition wall structure in accordance with yet another embodiment of the present disclosure.

The embodiment shown in FIG. 7 is different from the embodiment shown in FIG. 6 in that a first pixel defining layer PDL1, a second pixel defining layer PDL2, and a third pixel defining layer PDL3 have end portions that accord with one another in a plan view. The embodiment shown in FIG. 8 is different from the embodiment shown in FIG. 6 in that a first separator SEP1, a second separator SEP2, and a third separator SEP3 have end portions that accord with one another in a plan view.

Referring to FIG. 7, a first pixel defining layer PDL1, a second pixel defining layer PDL2, and a third pixel defining layer PDL3 may have end portions that accord with one another. The end portions of the first pixel defining layer PDL1, the second pixel defining layer PDL2, and the third pixel defining layer PDL3 may overlap with one another in a plan view. A first defining layer width PDL_W1, a second defining layer width PDL_W2, and a third defining layer width PDL_W3 may be the same.

The separator SEP in this embodiment of the present disclosure may have the same under-cut structure as in the above-described embodiment. Because the partition wall PW shown in FIG. 7 includes the separator SEP having the under-cut structure, a surface area on which the (2-2)th electrode ELT2-2 is adhered on the separator SEP when the (2-2)th electrode ELT2-2 is deposited on the non-display area NDA can be increased, and the lifting phenomenon of the (2-2)th electrode ELT2-2 in the non-display area NDA can be prevented.

Referring to FIG. 8, a first separator SEP1, a second separator SEP2, and a third separator SEP3 may have end portions that accord with one another. The end portions of the first separator SEP1, the second separator SEP2, and the third separator SEP3 may overlap with one another in a plan view. A first separator width SEP_W1, a second separator width SEP_W2, and a third separator width SEP_W3 may be the same.

A pixel defining layer PDL in this embodiment of the present disclosure may have the same structure as in embodiment shown in FIG. 6. Because curves are formed on the pixel defining layer PDL, a surface area of the pixel defining layer PDL, on which the (2-2)th electrode ELT2-2 can be deposited on the pixel defining layer PDL can be increased. Accordingly, adhesion between the (2-2)th electrode ELT2-2 and the pixel defining layer PDL can be increased, and the lifting phenomenon of the (2-2)th electrode ELT2-2 in the non-display area NDA can be prevented.

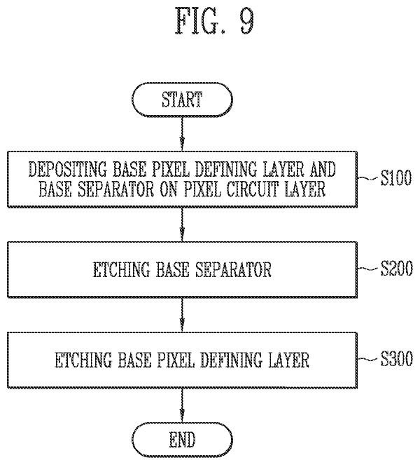

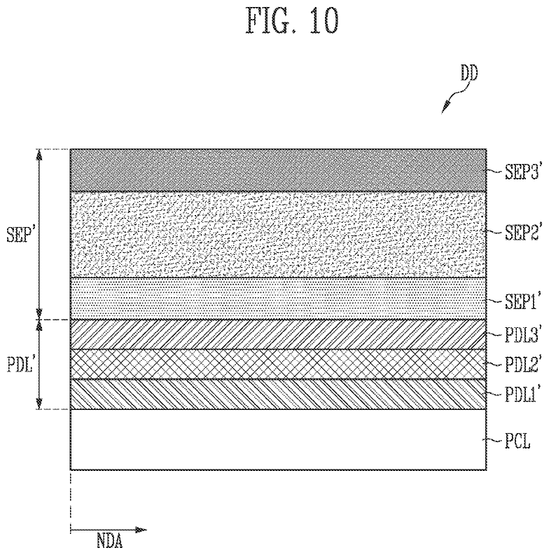

Hereinafter, a method of manufacturing a display device including a partition wall PW shown in FIG. 6 will be described with reference to FIGS. 9 to 13. FIG. 9 is a flowchart describing a method of manufacturing a display device in accordance with an embodiment of the present disclosure. FIGS. 10 to 13 are schematic cross-sectional views illustrating steps of the method of manufacturing the display device in accordance with an embodiment of the present disclosure. In FIGS. 10 to 13, connection electrodes CL are not illustrated to more clearly illustrate a structure of the partition wall PW disposed in a non-display area NDA while components of the display device DD, which are disposed in the non-display area NDA, are illustrated.

Referring to FIG. 9, the method of manufacturing the display device DD in accordance with an embodiment of the present disclosure may include step S100 of depositing a base pixel defining layer and a base separator on a pixel circuit layer, step S200 of etching the base separator, and step S300 of etching the base pixel defining layer.

Referring to FIG. 10, in the step S100 of depositing the base pixel defining layer and the base separator on the pixel circuit layer, a base pixel defining layer PDL′ may be deposited on a pixel circuit layer PCL, and a base separator SEP′ may be deposited on the base pixel defining layer PDL′. The base pixel defining layer PDL′ may entirely cover the pixel circuit layer PCL. The base separator SEP′ may entirely cover the base pixel defining layer PDL′. The base separator SEP′ may have an end portion that accords with an end portion of the base pixel defining layer PDL′. The end portion of the base separator SEP′ and the end portion of the base pixel defining layer PDL′ may overlap with each other in a plan view.

In the present disclosure, a process for depositing components of the display device DD may include at least one of a Chemical Vapor Deposition (CVD) process and an Atomic Layer Deposition (ALD) process. However, the present disclosure is not limited to a specific example.

The base pixel defining layer PDL′ may include a first base pixel defining layer PDL1′, a second base pixel defining layer PDL2′, and a third base pixel defining layer PDL3′.

The first base pixel defining layer PDL1′ may be deposited on the pixel circuit layer PCL. The second base pixel defining layer PDL2′ may be deposited on the first base pixel defining layer PDL1′. The third base pixel defining layer PDL3′ may be disposed on the second base pixel defining layer PDL2′.

The base pixel defining layer PDL′ may include an inorganic material. In some embodiments, the first base pixel defining layer PDL1′ and the third base pixel defining layer PDL3′ may include the same material, and the second base pixel defining layer PDL2′ may include a material different from the material of the first base pixel defining layer PDL1′ and the third base pixel defining layer PDL3′. For example, the first base pixel defining layer PDL1′ and the third base pixel defining layer PDL3′ may include silicon oxide (SiOₓ), and the second base pixel defining layer PDL2′ may include silicon nitride (SiNₓ). However, the present disclosure is not limited thereto.

In another embodiment, the base pixel defining layer PDL′ may include an organic material. For example, the base pixel defining layer PDL′ may include at least one selected from the group consisting of an acrylic resin, an epoxy resin, a phenolic resin, a polyamide resin, and a polyimide resin.

The base separator SEP′ may include a first base separator SEP1′, a second base separator SEP2′, and a third base separator SEP3′.

The first base separator SEP1′ may be deposited on the third base pixel defining layer PDL3′. The second base separator SEP2′ may be deposited on the first base separator SEP1′. The third base separator SEP3′ may be deposited on the second base separator SEP2′.

The base separator SEP′ may include an inorganic material. In some embodiments, the first base separator SEP1′ and the third base separator SEP3′ may include the same material, and the second base separator SEP2′ may include a material different from the material of the first base separator SEP1′ and the third base separator SEP3′. For example, the first base separator SEP1′ and the third base separator SEP3′ may include silicon nitride (SiNₓ), and the second base separator SEP2′ may include silicon oxide (SiOₓ).

In another embodiment, the base separator SEP′ may include an organic material. For example, the base separator SEP′ may include at least one selected from the group consisting of an acrylic resin, an epoxy resin, a phenolic resin, a polyamide resin, and a polyimide resin.

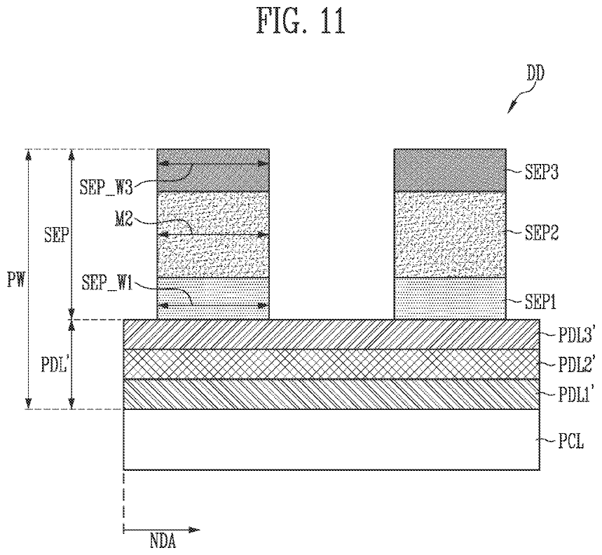

Referring to FIG. 11, in the step S200 of etching the base separator, the base separator SEP′ may be etched to have the same end portion. For example, the separator SEP′ may be etched to have end portions overlapping with each other in a plan view. In the present disclosure, the etching process may include at least one of wet etching and dry etching. However, the present disclosure is not limited to a specific example.

The base separator SEP′ may be etched to form an opening exposing the base pixel defining layer PDL′. The base separator SEP′ may be etched to form a separator SEP. The separator SEP may form a protrusion part on the base pixel defining layer PDL′.

The first base separator SEP1′ may be etched to form a first separator SEP1 having a first separator width SEP_W1. The second base separator SEP2′ may be etched to form a second separator SEP2 having a middle width M2. The third base separator SEP3′ may be etched to form a third separator SEP3 having a third separator width SEP_W3. The first separator width SEP_W1, the middle width M2, and the third separator width SEP_W3 may be the same. In some embodiments, the first separator width SEP_W1, the middle width M2, and the third separator width SEP_W3 may be the same width.

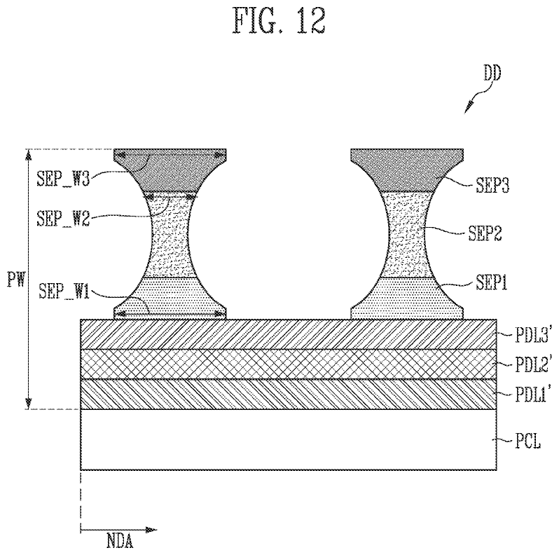

Referring to FIG. 12, in the step S200 of etching the base separator after the base separator SEP′ is etched to have the same end portion, the second separator SEP2 may be further selectively etched. Because the second separator SEP2 is further etched, the second separator SEP2 may have a second separator width SEP_W2. The second separator SEP2 may be etched relatively deep as compared with the first separator SEP1 and the third separator SEP3. The second separator SEP2 may be etched such that each of the first separator SEP1 and the third separator SEP3 forms a tip. The second separator width SEP_W2 may be smaller than each of the first separator width SEP_W1 and the third separator width SEP_W3.

The second separator SEP2 may be etched, to form an under-cut structure of the separator SEP. The second separator SEP2 may be etched, to form a curved surface. The second separator SEP2 may have a width different from the width of the first separator SEP1 and the third separator SEP3.

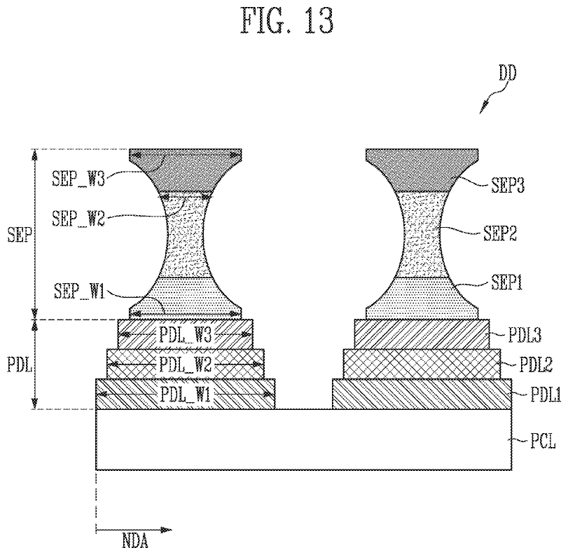

Referring to FIG. 13, in the step S300 of etching the base pixel defining layer, the base pixel defining layer PDL′ may be etched to form a pixel defining layer PDL. The pixel defining layer PDL may be etched to have a step-shaped section. In conjunction with FIG. 2, the pixel defining layer PDL may be etched to expose at least a portion of each of the connection electrodes CL.

The first base pixel defining layer PDL1′ may be etched to form a first pixel defining layer PDL1 having a first defining layer width PDL_W1. The first base pixel defining layer PDL1′ may be etched to have the first defining layer width PDL_W1, which is thickest in the partition wall PW. The second base pixel defining layer PDL2′ may be etched to form a second pixel defining layer PDL2 having a second defining layer width PDL_W2. The second base pixel defining layer PDL2′ may be etched to have the second defining layer width PDL_W2, which is smaller than the first defining layer width PDL_W1. The third base pixel defining layer PDL3′ may be etched to form a third pixel defining layer PDL3 having a third defining layer width PDL_W3. The third base pixel defining layer PDL3′ may be etched to having the third defining layer width PDL_W3, which is smaller than the second defining layer width PDL_W2. The third defining layer width PDL_W3 may be larger than the first separator width SEP_W1. However, the present disclosure is not limited thereto. The third defining layer width PDL_W3 may be equal to the first separator width SEP_W1.

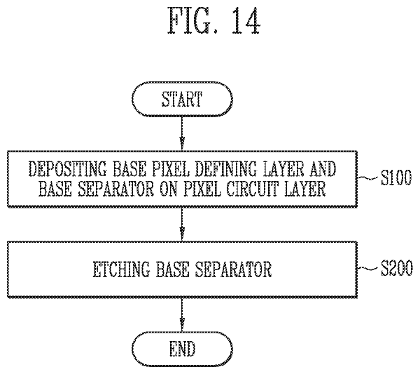

Hereinafter, a method of manufacturing a display device including a partition wall PW in accordance with another embodiment of the present disclosure will be described with reference to FIGS. 10 to 12 and 14. FIG. 14 is a flowchart describing a method of manufacturing a display device in accordance with an embodiment of the present disclosure. FIG. 14 is a flowchart illustrating a method of manufacturing the partition wall PW shown in FIG. 7. In FIG. 14, descriptions of portions that are the same or substantially the same as those described above will not be repeated.

Referring to FIG. 14, the method of manufacturing the display device DD in accordance with an embodiment of the present disclosure may include step S100 of depositing a base pixel defining layer and a base separator on a pixel circuit layer and step S200 of etching the base separator.

Referring to FIGS. 10 to 12, in the step S100 of depositing the base pixel defining layer and the base separator on the pixel circuit layer, a base pixel defining layer PDL′ may be deposited on a pixel circuit layer PCL, and a base separator SEP′ may be deposited on the base pixel defining layer PDL′.

In the step S200 of etching the base separator, the base separator SEP′ may be etched such that a separator SEP forms an under-cut structure.

The method of manufacturing the partition wall PW in accordance with an embodiment of the present disclosure may not include the step S300 of etching the base pixel defining layer. Because the base pixel defining layer is not etched, a pixel defining layer PDL may have end portions that accord with one another. For example, a first base pixel defining layer PDL1′, a second base pixel defining layer PDL2′, and a third base pixel defining layer PDL3′ may have end portions that accord with one another. The first base pixel defining layer PDL1′, the second base pixel defining layer PDL2′, and the third base pixel defining layer PDL3′ may have end portions overlapping with one another in a plan view. The pixel defining layer PDL may not be etched to expose at least a portion of each of the connection electrodes CL.

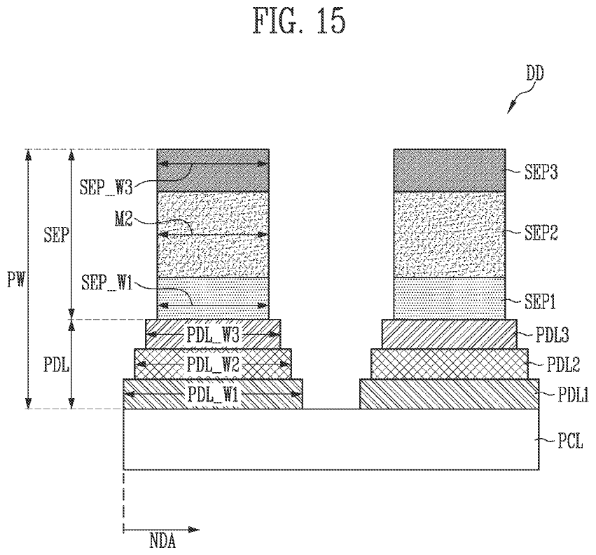

Hereinafter, a method of manufacturing a display device including a partition wall PW as shown in FIG. 8 will be described with reference to FIGS. 9 to 11 and 15. FIG. 15 is a schematic cross-sectional view illustrating a step of a method of manufacturing a display device in accordance with an embodiment of the present disclosure. In FIG. 15, connection electrodes CL are not illustrated to more clearly illustrate a structure of the partition wall PW.

Referring to FIG. 9, the method of manufacturing the display device DD in accordance with an embodiment of the present disclosure may include step S100 of depositing a base pixel defining layer and a base separator on a pixel circuit layer, step S200 of etching the base separator, and step S300 of etching the base pixel defining layer.

Referring to FIG. 10, in the step S100 of depositing the base pixel defining layer and the base separator on the pixel circuit layer, a pixel circuit layer PCL may be formed, a base pixel defining layer PDL′ may be deposited on the pixel circuit layer PCL, and a base separator SEP′ may be deposited on the base pixel defining layer PDL′.

Referring to FIG. 11, in the step S200 of etching the base separator, the base separator SEP′ may be etched to have the same end portion. The base separator SEP′ may be etched to have end portions overlapping with one another on a plane. The method in accordance with an embodiment of the present disclosure may not include the step of selectively etching the second separator SEP2 in the step S200 of etching the base separator. Accordingly, the separator SEP may have the same end portion.

Referring to FIG. 15, in the step S300 of etching the base pixel defining layer, the base pixel defining layer PDL′ may be etched to form a pixel defining layer PDL. The pixel defining layer PDL may be etched to have a step-shaped section.

According to the method of manufacturing the display device DD in accordance with embodiments of the present disclosure, the partition wall PW forming a protrusion structure is disposed in the non-display area NDA. Because the protrusion structure of the partition wall PW forms the protrusion structure, the surface area on which the (2-2)th electrode ELT2-2 can be deposited is increased. The contact area of the (2-2)th electrode ELT2-2 having a lower layer on which the (2-2)th electrode ELT2-2 is deposited can be increased, and accordingly, the adhesion of the (2-2)th electrode ELT2-2 with a surface on which the (2-2)th electrode ELT2-2 is deposited can be increased. Thus, the lifting phenomenon of the (2-2)th electrode ELT2-2 can be prevented.

In accordance with embodiments of the present disclosure, a display device and a method of manufacturing the display device are provided in which a lifting risk of an electrode of the display device in a non-display area can be reduced.

Example embodiments have been disclosed herein, and although specific terms are employed, they are used and are to be interpreted in a generic and descriptive sense and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims and their equivalents.

What is claimed is:

1. A display device comprising:
pixels arranged in a display area;
a pixel circuit layer comprising a pixel circuit; and
a partition wall on the pixel circuit layer in the display area and in a non-display area, the non-display area being an area other than the display area, the partition wall comprising a pixel defining layer and a separator on the pixel defining layer,
wherein, in the non-display area, one end portion of the pixel defining layer and one end portion of the separator do not overlap with each other in a plan view.

2. The display device of claim 1, wherein the pixel defining layer comprises:
a first pixel defining layer on the pixel circuit layer, the first pixel defining layer having a first defining layer width; and
a second pixel defining layer on the first pixel defining layer, the second pixel defining layer having a second defining layer width, and
wherein the separator comprises:
a first separator on the pixel defining layer, the first separator having a first separator width; and
a second separator on the first separator, the second separator having a second separator width.

3. The display device of claim 2, wherein the first defining layer width is larger than the second defining layer width, and
wherein the pixel defining layer has a non-flat side surface.

4. The display device of claim 2, wherein the first separator width is smaller than the second defining layer width, and
wherein the second separator width is smaller than the first separator width.

5. The display device of claim 4, wherein the separator has a curved surface, and
wherein the second separator is inward of the first separator in a direction in which a plane on which the pixel circuit layer is arranged extends.

6. The display device of claim 2, wherein the pixel defining layer further comprises a third pixel defining layer on the second pixel defining layer, the third pixel defining layer having a third defining layer width, and
wherein the separator further comprises a third separator on the second separator, the third separator having a third separator width.

7. The display device of claim 6, wherein end portions of the first pixel defining layer, the second pixel defining layer, and the third pixel defining layer do not overlap with each other in the plan view.

8. The display device of claim 6, wherein end portions of the first pixel defining layer, the second pixel defining layer, and the third pixel defining layer overlap with each other in the plan view.

9. The display device of claim 7, wherein end portions of the first separator and the third pixel defining layer do not overlap with each other in the plan view, and
wherein the second separator width is smaller than each of the first separator width and the third separator width.

10. The display device of claim 7, wherein end portions of the first separator and the third pixel defining layer do not overlap with each other in the plan view, and
wherein the first separator width, the second separator width, and the third separator width are the same.

11. The display device of claim 8, wherein end portions of the first separator and the third pixel defining layer do not overlap with each other in the plan view, and
wherein the second separator width is smaller than each of the first separator width and the third separator width.

12. The display device of claim 9, further comprising a first electrode and a second electrode on the pixel circuit layer,
wherein the second electrode comprises a (2-1)th electrode in the display area and a (2-2)th electrode in the non-display area, and
wherein the (2-2)th electrode is on the partition wall.

13. The display device of claim 12, wherein the (2-2)th electrode covers side surfaces of the pixel defining layer and the separator.

14. A method of manufacturing a display device having a display area in which pixels are arranged and a non-display area that is other than the display area, the method comprising:
depositing a base pixel defining layer on a pixel circuit layer in the display area and the non-display area and depositing a base separator on the base pixel defining layer; and
etching the base separator, the etching of the base separator comprising etching the base separator such that the base separator in the non-display area exposes at least a portion of the base pixel defining layer.

15. The method of claim 14, wherein the depositing of the base pixel defining layer comprises depositing a first base pixel defining layer on the pixel circuit layer and depositing a second base pixel defining layer on the first base pixel defining layer, and
wherein the depositing of the base separator comprises depositing a first base separator on the base pixel defining layer and depositing a second base separator on the first base separator.

16. The method of claim 15, wherein the etching of the base separator comprises etching the base separator such that the first base separator and the second base separator have the same width.

17. The method of claim 16, wherein the etching of the base separator further comprises etching the second base separator deeper than the first base separator such that the first base separator has a first separator width and the second base separator has a second separator width, and
wherein the second separator width is smaller than the first separator width.

18. The method of claim 16, further comprising etching the base pixel defining layer such that a first pixel defining layer is formed having a first defining layer width by etching the first base pixel defining layer, and a second pixel defining layer is formed having a second defining layer width smaller than the first defining layer width by etching the second base pixel defining layer.

19. A method of manufacturing a display device having a display area in which pixels are arranged and a non-display area that is other than the display area, the method comprising:
depositing a base pixel defining layer on a pixel circuit layer in the display area and the non-display area and depositing a base separator on the base pixel defining layer;
etching the base separator; and
etching the base pixel defining layer,
wherein the depositing of the base pixel defining layer comprises depositing a first base pixel defining layer on the pixel circuit layer and depositing a second base pixel defining layer on the first base pixel defining layer,
wherein the depositing of the base separator comprises depositing a first base separator on the base pixel defining layer and depositing a second base separator on the first base separator,
wherein the etching of the base pixel defining layer comprises etching the first base pixel defining layer to form a first pixel defining layer having a first defining layer width, and etching the second base pixel defining layer to form a second pixel defining layer having a second defining layer width that is smaller than the first defining layer width, and
wherein an end portion of the first pixel defining layer and an end portion of the second pixel defining layer do not overlap with each other in a plan view.

20. The method of claim 19, wherein the etching of the base separator comprises etching the first base separator to form a first separator having a first separator width, and etching the second base separator to form a second separator having a second separator width that is smaller than the first separator width,
wherein each of the base separator and the base pixel defining layer comprises an inorganic material, and
wherein the inorganic material comprises at least one selected from the group consisting of silicon nitride and silicon oxide.
